(19) United States
(12) Patent Application Publication
(10) Pub. No.: US 2006/0009014 A1
(43) Pub. Date: Jan. 12, 2006

(54) Method of fabricating a poly-crystalline silicon thin film and method of fabricating a semiconductor device using the same

(76) Inventors: Do-young Kim, Suwon-si (KR); Takashi Noguchi, Seongnam-si (KR); Hans S. Cho, Seoul (KR); Jung-yeon Kwon, Seongnam-si (KR)

Correspondence Address: LEE & MORSE, P.C., 1101 WILSON BOULEVARD, SUITE 2000, ARLINGTON, VA, 22209, US

(21) Appl. No.: 11/174,649

(22) Filed: Jul. 6, 2005

(30) Foreign Application Priority Data
Jul. 8, 2004 (KR) 10-2004-0052981

(51) Int. Cl. H01L 21/20; H01L 21/36

(52) U.S. Cl. 438/486

(57) ABSTRACT

A method of fabricating a poly-crystalline silicon thin film, and a method of fabricating a semiconductor device using the same, includes implanting predominantly neutralized ions into an amorphous silicon thin film formed on a substrate. The thin film may be annealed. Glass, silicon and other substrates, such as heat intolerant substrates, e.g., plastic, may be employed. Eximer laser annealing using relatively high energy densities may be employed. Thin film transistors and numerous other semiconductor devices may be formed using the poly-crystalline silicon thin film.

### BACKGROUND OF THE INVENTION

1. Field of the Invention

The present invention relates to a method of fabricating a poly-crystalline silicon (poly-Si) thin film and a method of fabricating a semiconductor device using the same. More particularly, the present invention relates to a method of fabricating a poly-Si thin film having a large crystal grain size, and a method of fabricating an electronic device using the same.

2. Description of the Related Art

Poly-Si has applications in a variety of electronic devices such as flat panel displays and solar cells, and has greater mobility than amorphous silicon (a-Si). Poly-Si-based electronic devices may be formed on a substrate of a heat resistant material, e.g., glass. Conventionally, when a poly-Si thin film is fabricated on a heat resistant substrate such as a silicon (Si) or glass substrate, high-temperature deposition processes, e.g., chemical vapor deposition (CVD) or plasma enhanced CVD (PECVD), are used to deposit an a-Si film, which is subsequently transformed into poly-Si. The maximum size of poly-Si crystal grains obtained by these conventional methods is generally 3000 to 4000 Å and obtaining a grain size of 4000 Å or higher may be difficult. Accordingly, improvements are needed in the fabrication of poly-Si thin films having a large grain size.

Poly-Si electronic devices on plastic substrates, e.g., flat panel displays, have been developed because plastic substrates may be lightweight, flexible and firm. However, while fabrication of poly-Si electronic devices on plastic substrates is known, in order to prevent thermal deformations, it may be necessary to use low temperature silicon layer forming processes, e.g., sputtering, by which poly-Si electronic devices may be formed at low temperatures. The low temperature processes may be required to prevent thermal shock to the substrate and to suppress defects that may occur if the fabrication processes involve higher temperatures.

One approach for avoiding or preventing damage to a plastic substrate when forming a structure, e.g., a Si channel, on a plastic substrate involves low temperature deposition of a silicon layer and subsequently using eximer laser annealing (ELA) to crystallize the silicon layer. However, as 10-20% hydrogen may remain in an a-Si film formed by, e.g., low temperature CVD or PECVD a-Si film deposition, the remnant gas may promote the occurrence of Si crystal defects upon annealing the film.

In order to avoid occurrence of defects due to hydrogen, other processes use physical vapor deposition PVD, e.g., sputtering. Sputtering using an inert gas, e.g., argon (Ar), may be employed and may result in about 1-3% of Ar remaining in the resulting a-Si film. As sputtering uses an inert gas and avoids leaving hydrogen in the film, this may provide an improved a-Si film as compared to the CVD or PECVD processes described above, as a lower percentage of gas in the poly-Si film may result in an improved poly-Si film.

Another problem with conventional processes is that silicon films formed by the conventional processes may be separated from a heat intolerant substrate such as a plastic substrate during annealing. Thus, it may be difficult to perform annealing at a suitably high energy level while still obtaining acceptable poly-Si films.

### SUMMARY OF THE INVENTION

The present invention is therefore directed to a method of fabricating a poly-Si thin film and a method of fabricating an electronic device using the same, in which a poly-Si thin film having a large grain size may be formed, which substantially overcome one or more of the problems due to the limitations and disadvantages of the related art.

It is therefore a feature of an embodiment of the present invention to provide a method of fabricating an improved poly-Si thin film and a method of fabricating an electronic device using the same, in which a poly-Si thin film having a large grain size may be fabricated using an a-Si thin film formed at a low temperature.

It is therefore another feature of an embodiment of the present invention to provide a method of fabricating an improved poly-Si thin film using low cost processes.

At least one of the above and other features and advantages of the present invention may be realized by providing a method of fabricating a poly-crystalline silicon thin film, including forming an amorphous silicon thin film on a substrate, implanting a material into the amorphous silicon thin film using ion implantation, wherein the material is predominantly neutralized ions, and annealing the amorphous silicon thin film, after implanting the material, to form the poly-crystalline silicon thin film.

The substrate may include a silicon substrate, a glass substrate, and/or a plastic substrate. Forming the amorphous silicon thin film on the substrate may include physical vapor deposition and may include using argon or xenon. The neutralized ions may include ions of silicon, germanium, argon, and/or carbon. The annealing may include eximer laser annealing and may include irradiation at an energy density of greater than about 200 mJ/cm2.

At least one of the above and other features and advantages of the present invention may also be realized by providing a method of fabricating a semiconductor device, including providing a substrate, forming an amorphous silicon layer on the substrate, using ion implantation to implant predominantly neutralized ions into the amorphous silicon layer, annealing the amorphous silicon layer, after implanting the neutralized ions, to form a poly-crystalline layer, and implanting a dopant into the poly-crystalline layer, after annealing the amorphous silicon layer, to form a source region and a drain region.

The method may further include annealing the source and drain regions after implanting the dopant into the poly-crystalline layer. The substrate may include a silicon substrate, a glass substrate, and a plastic substrate. Forming the amorphous silicon layer on the substrate may include physical vapor deposition using sputtering. The neutralized ions may include ions of silicon, germanium, argon, and/or carbon. The neutralized ions may be ions of silicon. The annealing may include eximer laser annealing.

At least one of the above and other features and advantages of the present invention may further be realized by providing a method of fabricating a thin film transistor, including providing a substrate, forming an amorphous silicon thin film on the substrate, using ion implantation to implant predominantly neutralized ions into the amorphous silicon thin film, performing a first annealing to anneal the amorphous silicon thin film to form a poly-crystalline silicon thin film, forming two active regions in the poly-crystalline silicon thin film by implanting a dopant, the two active regions having a channel region disposed between them, and forming a gate on the channel region.

Forming the two active regions further may include performing a second annealing after implanting the dopant. The substrate may include a silicon substrate, a glass substrate, and/or a plastic substrate. The amorphous silicon thin film may be formed using sputtering. The neutralized ions may include ions of silicon, germanium, argon, and/or carbon. The first annealing may include eximer laser annealing.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A through 1D illustrate cross-sectional views of stages in a method of fabricating a poly-Si thin film according to an embodiment of the present invention;

FIGS. 2A(1) and 2A(2) illustrate scanning electron microscope photographs of poly-Si thin films fabricated according to conventional methods;

FIG. 2B illustrates a scanning electron microscope photograph of a poly-Si thin film fabricated according to an embodiment of the present invention;

FIG. 3A illustrates a transmission electron microscope photograph of an a-Si thin film fabricated according to a conventional method;

FIG. 3B illustrates a transmission electron microscope photograph of an a-Si thin film fabricated according to an embodiment of the present invention;

FIG. 4 illustrates a flowchart for a method of fabricating a thin film transistor according to an embodiment of the present invention; and

FIG. 5 illustrates a cross-sectional view of a thin film transistor fabricated according to an embodiment of the present invention.

### DETAILED DESCRIPTION OF THE INVENTION

Korean Patent Application No. 10-2004-0052981, filed on Jul. 8, 2004, in the Korean Intellectual Property Office, and entitled: “METHOD OF FABRICATING POLY-CRYSTALLINE SILICON THIN FILM AND METHOD OF FABRICATING SEMICONDUCTOR DEVICE USING THE SAME,” is incorporated by reference herein in its entirety.

Hereinafter, a method of fabricating a poly-Si thin film, and a method of fabricating a thin film transistor (TFT) using the same, according to embodiments of the present invention will be described in detail.

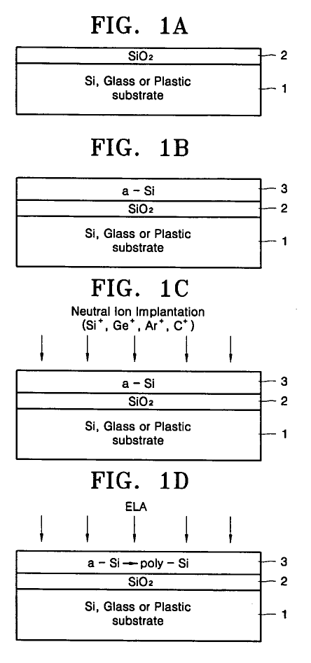

FIGS. 1A through 1D illustrate cross-sectional views of stages in a method of fabricating a poly-Si thin film according to an embodiment of the present invention, which may include implanting neutralized ions, e.g., Si+ ions. Referring to FIG. 1A, a substrate 1, e.g., a silicon (Si) wafer or a glass or plastic substrate, may be prepared for formation of a poly-Si thin film. An oxide layer 2, e.g., a SiO₂ layer, may be formed on the substrate 1 to help ensure electrical insulation. If a silicon wafer is used as the substrate 1 instead of a glass or plastic substrate, a native oxide layer may be formed thereon.

Referring to FIG. 1B, an a-Si thin film 3 may be formed on the substrate 1. The a-Si thin film 3 may be formed by a physical vapor deposition (PVD) process, e.g., sputtering, to allow for low temperature deposition. The sputtering gas used for sputtering may include an inert gas, e.g., argon (Ar), xenon (Xe), etc. The thickness of the a-Si thin film 3 may be about 50 nm. A sputtering power of 200 W and a gas pressure of 5 mTorr may be used during sputtering.

Referring to FIG. 1C, neutralized ions, e.g., Si+ ions, may be implanted into the a-Si thin film 3. The neutralized ions may include ions of Si, germanium (Ge), Ar, and/or carbon (C). Preferably, Si ions are used as the neutralized ions. The ion implantation process may be performed using a known ion implanting apparatus. The implantation of the neutralized ions, e.g., Si+ ions, may cause ion bombardment in the a-Si thin film 3 such that a portion of the implanted neutralized ions penetrates the a-Si thin film 3.

Referring to FIG. 1D, the a-Si thin film 3 implanted with the neutralized ions may be annealed, e.g., in a furnace or by eximer laser annealing (ELA), to obtain a poly-Si thin film. Preferably, the annealing of the a-Si thin film 3 may be performed using ELA.

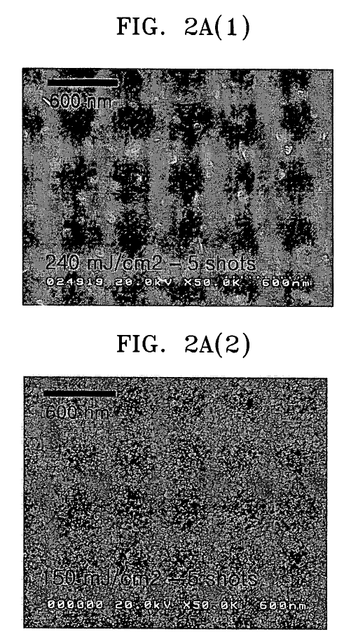

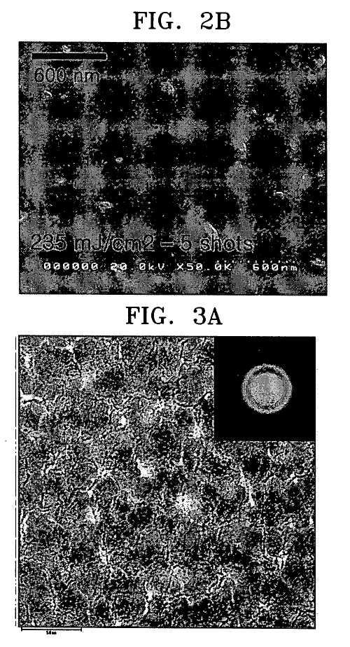

FIGS. 2A(1) and 2A(2) illustrate scanning electron microscope (SEM) photographs of poly-Si thin films fabricated according to conventional methods, and FIG. 2B illustrates a SEM photograph of a poly-Si thin film fabricated according to an embodiment of the present invention, wherein a poly-Si thin film is formed by implanting neutralized Si+ ions into an a-Si thin film. The samples illustrated in FIGS. 2A(1), 2A(2) and 2B were prepared by forming a 50 nm thick a-Si thin film using sputtering at room temperature. The conventional sample illustrated in FIG. 2A(1) was annealed by irradiation using the eximer laser five times at an energy density of 240 mJ/cm² with a duration of 20 ns, while the other conventional sample, illustrated in FIG. 2A(2), was irradiated five times at an energy density of 150 mJ/cm² with a duration of 20 ns. The sample illustrated in FIG. 2B, prepared according to the present invention, was annealed by irradiation using an eximer laser five times at an energy density of 235 mJ/cm² with a duration of 20 ns.

The poly-Si thin film illustrated in FIG. 2B exhibits a grain size of about 600 to 800 nm, whereas the conventional poly-Si thin film illustrated in FIG. 2A(1) exhibits a grain size of about 200 to 300 nm and the poly-Si thin film illustrated in FIG. 2A(2) exhibits a significantly smaller grain size. As can be seen from these examples, the method of the present invention may provide a poly-Si thin film exhibiting a larger gain size than one prepared by conventional methods.

In methods according to the present invention, a gas domain of an inert gas, e.g., Ar, which is used for sputtering and may remain in an a-Si thin film, may be decomposed due to neutralized ion bombardment during the implantation of neutralized ions. Also, neutralized ion implantation, by transiting partial crystal grains which may exist in the a-Si thin film into an amorphous phase, may promote more uniform crystallization of a-Si grains into poly-Si grains during annealing. As a result, growth of crystal grains having a larger size may be promoted.

Methods of fabrication according to the present invention may enable the formation of an improved poly-Si thin film while annealing with a more suitable energy, such as roughly 250 mJ/cm². Tables 1 and 2 illustrate experimental results of heat tolerance during annealing for poly-Si thin films fabricated according to conventional methods and methods of the present invention, respectively.

TABLE 1
Without Si+ implantation

| | | | Energy density (mJ/cm2) | | | | | | | | | | | |
|---|---|---|---|---|---|---|---|---|---|---|---|---|---|---|
| | | | 100 | 150 | 170 | 200 | 235 | 250 | 275 | 300 | 315 | 330 | 340 | 350 |
| Ar | The number | 1 | ◯ | ◯ | | X | | | | | | | | |
| | of shots | 2 | ◯ | ◯ | | | | | | | | | | |
| | (shots) | 5 | ◯ | ◯ | | | | | | | | | | |
| | | 10 | ◯ | ◯ | | | | | | | | | | |
| | | 20 | ◯ | X | | | | | | | | | | |
| | | 30 | ◯ | X | | | | | | | | | | |
| Xe | The number | 1 | ◯ | ◯ | | X | | | | | | | | |
| | of shots | 2 | ◯ | ◯ | | | | | | | | | | |
| | (shots) | 5 | ◯ | ◯ | | | | | | | | | | |
| | | 10 | ◯ | X | | | | | | | | | | |
| | | 20 | | | | | | | | | | | | |
| | | 30 | | | | | | | | | | | | |

TABLE 2
With Si+ implantation

| | | | Energy density (mJ/cm2) | | | | | | | | | | | |
|---|---|---|---|---|---|---|---|---|---|---|---|---|---|---|
| | | | 100 | 150 | 170 | 200 | 235 | 250 | 275 | 300 | 315 | 330 | 340 | 350 |
| Ar | The number | 1 | | | ◯ | ◯ | ◯ | ◯ | X | | | | | |
| | of shots | 2 | | | | | ◯ | X | | | | | | |
| | (shots) | 5 | | | | | X | | | | | | | |
| | | 10 | | | | | | | | | | | | |
| | | 20 | | | | | | | | | | | | |
| | | 30 | | | | | | | | | | | | |
| Xe | The number | 1 | | | ◯ | ◯ | ◯ | ◯ | ◯ | ◯ | ◯ | ◯ | | |
| | of shots | 2 | | | | | ◯ | | | | | | | |
| | (shots) | 5 | | | | | ◯ | ◯ | | | | | | |
| | | 10 | | | | | | | | | | | | |
| | | 20 | | | | | | | | | | | | |
| | | 30 | | | | | | | | | | | | |

Tables 1 and 2 illustrate that the methods of the present invention may allow for fabrication of an improved poly-Si thin film. In Tables 1 and 2, ∘ and X marks correspond to experimental samples, where ∘ indicates a case where poly-Si remains after each annealing shot is performed, and X indicates a case where separation or damage of the poly-Si layer was caused by annealing. As illustrated in Table 1, a thin film made according to conventional methods, which is not implanted with neutralized ions, may be decomposed or damaged at a relatively low energy density of 200 mJ/cm². In contrast, as illustrated in Table 2, a thin film made by methods according to the present invention may exhibit successful formation of poly-Si at an energy density of 200 mJ/cm2 or higher. As also illustrated in Table 2, methods according to the present invention that employ Ar sputtering may allow for formation of a more stable poly-Si thin film than is formed using Xe sputtering.

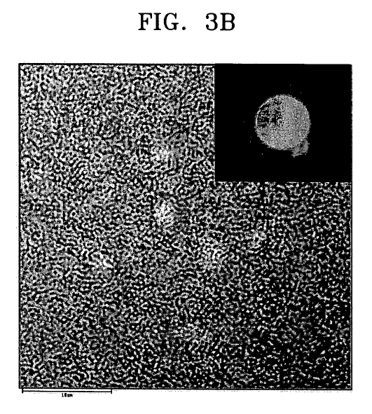

FIG. 3A illustrates a transmission electron microscope (TEM) photograph of an a-Si thin film fabricated according to a conventional method, and FIG. 3B illustrates a TEM photograph of an a-Si thin film fabricated according to an embodiment of the present invention (note that the TEM photograph illustrated in FIG. 3B is a more magnified view than that illustrated in FIG. 3A). As illustrated in FIG. 3A, a conventionally fabricated a-Si thin film may exhibit significant grain boundaries, which are indicative of crystalline structures throughout the amorphous phase. In contrast, an a-Si thin film fabricated according to the present invention, as illustrated in FIG. 3B, may exhibit fewer boundaries and may be more uniform. Accordingly, an a-Si thin film fabricated according to the present invention may yield more highly uniform poly-Si thin films after annealing.

The inset images in FIGS. 3A and 3B illustrate electronic diffraction patterns of a-Si thin films prepared according to the conventional method and the method of the present invention, respectively. As can be seen from the inset images, an a-Si thin film formed according to methods of the present invention (FIG. 3B) may exhibit greater uniformity than a conventionally formed a-Si thin film (FIG. 3A).

Methods of the present invention may be employed in fabrication of a semiconductor device, e.g., a TFT, by combining the methods of the present invention with other processes, as will now be briefly described. In a TFT fabrication method according to an embodiment of the present invention, a TFT including a poly-Si film may be fabricated at room temperature, or higher, as is suitable for the materials involved. Therefore, a TFT having improved characteristics may be fabricated on a heat-intolerant substrate such as a plastic substrate, or on a silicon wafer.

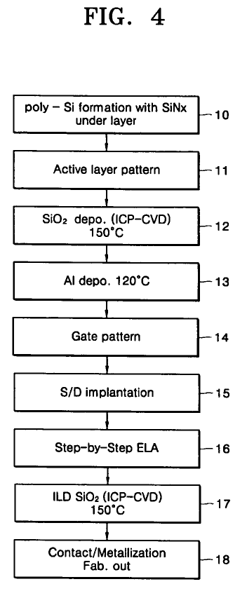

FIG. 4 illustrates a flowchart for a method of fabricating a TFT according to an embodiment of the present invention. A silicon nitride (SiNₓ) layer may be formed on a substrate, and a poly-Si thin film may be formed on the SiNₓ layer. An a-Si thin film is formed on the substrate using a process such as PVD, as described above, and then ELA is performed to form the poly-Si thin film. Formation of the a-Si thin film may involve the deposition of a-Si using Xe sputtering. After deposition, the a-Si thin film is implanted with neutralized ions, e.g., neutralized Si+ ions, and may be step-by-step annealed by a process such as ELA to form the poly-Si thin film (operation 10).

The resultant poly-Si thin film may be patterned to form an active region using a conventional patterning process, e.g., a reactive ion beam etch (RIE) (operation 11). Thereafter, an SiO₂ thin film may be formed as a gate insulting layer (operation 12).

A metal layer, such as an aluminum (Al) layer, may be deposited at a temperature of, for example, 120° C., on a surface of the resultant structure (operation 13) and patterned to complete a gate electrode (operation 14). To form source (s) and drain (d) regions, impurity ions may be implanted (operation 15) and annealed by ELA (operation 16).

SiO₂ may be deposited on the resultant structure as an intermetal dielectric by a process such as inductively coupled plasma chemical vapor deposition (ICP-CVD) at a temperature of 150° C. (operation 17). Contact holes and metal patterns may be formed (operation 18) to complete the poly-Si TFT.

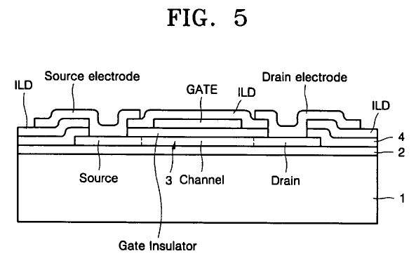

FIG. 5 illustrates a cross-sectional view of a thin film transistor fabricated according to an embodiment of the present invention. Referring to FIG. 5, an insulation layer 2 may be formed on a substrate 1. On the insulation layer 2, a poly-Si thin film 3 may be formed and divided into source and drain regions with a channel region disposed between them. A gate insulating layer 4 may be formed on the poly-Si thin film 3. In portions of the gate insulating layer 4 corresponding to the source and drain regions, holes may be formed to allow the source and drain regions to contact source and drain electrodes, respectively. A gate (gate electrode) may be formed over the channel region, and an interlayer dielectric (ILD) may be formed thereon. Holes may be formed in portions of the ILD corresponding to the source and drain regions. Source and drain electrodes may be connected to the source and drain regions, respectively.

According to methods of the present invention, an improved poly-Si thin film and a semiconductor device including the same may be formed. Before performing an annealing, neutralized ions may be implanted into an a-Si thin film, resulting in formation of an improved poly-Si thin film. The fabrication method of the present invention may be applied to formation of poly-Si thin films on a variety of substrates, including silicon wafers, glass substrates and heat intolerant substrates such as a plastic substrates.

Poly-Si thin films formed according to methods of the present invention may be used as a complete product or as a single component adapted for use in an electronic device, and may be applied to a variety of devices including TFTs, solar cells, flat panel displays, AMLCDs, AMOLEDs, a memory devices, etc., without departing from the scope of the present invention. Poly-Si thin films formed according to methods of the present invention may be used for a TFT having a high mobility, fast response speed and using a plastic substrate. Such a TFT may be applied to any electronic device.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a poly-crystalline silicon thin film, the method comprising:
forming an amorphous silicon thin film on a substrate;
implanting a material into the amorphous silicon thin film using ion implantation, wherein the material is predominantly neutralized ions; and
annealing the amorphous silicon thin film, after implanting the material, to form the poly-crystalline silicon thin film.

2. The method as claimed in claim 1, wherein the substrate is a substrate selected from the group consisting of a silicon substrate, a glass substrate, and a plastic substrate.

3. The method as claimed in claim 1, wherein forming the amorphous silicon thin film on the substrate includes physical vapor deposition.

4. The method as claimed in claim 3, wherein the physical vapor deposition includes sputtering using argon or xenon.

5. The method as claimed in claim 1, wherein the neutralized ions are ions of one selected from the group consisting of silicon, germanium, argon, and carbon.

6. The method as claimed in claim 5, wherein the neutralized ions are ions of silicon.

7. The method as claimed in claim 1, wherein the annealing includes eximer laser annealing.

8. The method as claimed in claim 7, wherein the eximer laser annealing includes irradiation at an energy density of greater than about 200 mJ/cm².

9. A method of fabricating a semiconductor device, comprising:
providing a substrate;
forming an amorphous silicon layer on the substrate;
using ion implantation to implant predominantly neutralized ions into the amorphous silicon layer;
annealing the amorphous silicon layer, after implanting the neutralized ions, to form a poly-crystalline layer; and
implanting a dopant into the poly-crystalline layer, after annealing the amorphous silicon layer, to form a source region and a drain region.

10. The method as claimed in claim 9, further comprising annealing the source and drain regions after implanting the dopant into the poly-crystalline layer.

11. The method as claimed in claim 9, wherein the substrate is a substrate selected from the group consisting of a silicon substrate, a glass substrate, and a plastic substrate.

12. The method as claimed in claim 9, wherein forming the amorphous silicon layer on the substrate includes physical vapor deposition using sputtering.

13. The method as claimed in claim 9, wherein the neutralized ions are ions of one selected from the group consisting of silicon, germanium, argon, and carbon.

14. The method as claimed in claim 9, wherein the annealing includes eximer laser annealing.

15. A method of fabricating a thin film transistor, comprising:
providing a substrate;
forming an amorphous silicon thin film on the substrate;
using ion implantation to implant predominantly neutralized ions into the amorphous silicon thin film;
performing a first annealing to anneal the amorphous silicon thin film to form a poly-crystalline silicon thin film;
forming two active regions in the poly-crystalline silicon thin film by implanting a dopant, the two active regions having a channel region disposed between them; and
forming a gate on the channel region.

16. The method as claimed in claim 15, wherein forming the two active regions further includes performing a second annealing after implanting the dopant.

17. The method as claimed in claim 15, wherein the substrate is a substrate selected from the group consisting of a silicon substrate, a glass substrate, and a plastic substrate.

18. The method as claimed in claim 15, wherein the amorphous silicon thin film is formed using sputtering.

19. The method as claimed in claim 15, wherein the neutralized ions are ions of one selected from the group consisting of silicon, germanium, argon, and carbon.

20. The method as claimed in claim 15, wherein the first annealing includes eximer laser annealing.
